(19) United States
(12) Patent Application Publication
(10) Pub. No.: US 2024/0284802 A1
(43) Pub. Date: Aug. 22, 2024

(54) MAGNETIC MEMORY DEVICE AND METHOD FOR FABRICATING THE SAME

(71) Applicant: Samsung Electronics Co., Ltd., Suwon-si (KR)

(72) Inventors: Hee Ju SHIN, Suwon-si (KR); Se Chung OH, Suwon-si (KR); Jun Ho JEONG, Suwon-si (KR)

(73) Assignee: Samsung Electronics Co., Ltd., Suwon-si (KR)

(21) Appl. No.: 18/242,084

(22) Filed: Sep. 5, 2023

(30) Foreign Application Priority Data
Feb. 21, 2023 (KR) 10-2023-0022608

(51) Int. Cl. H10N 50/20; H10B 61/00; H10N 50/01; H10N 50/80; H10N 50/85

(52) U.S. Cl. CPC H10N 50/20; H10B 61/22; H10N 50/01; H10N 50/80; H10N 50/85

(57) ABSTRACT

A magnetic memory device and a method for fabricating the same are provided. The magnetic memory device includes a pinned layer pattern, a free layer pattern including boron (B), a tunnel barrier layer pattern between the pinned layer pattern and the free layer pattern, an oxide layer pattern spaced apart from the tunnel barrier layer pattern with the free layer pattern therebetween, the oxide layer pattern including a metal borate, and a capping layer pattern spaced apart from the free layer pattern with the oxide layer pattern therebetween, the capping layer pattern including a metal boride, wherein a difference between a boron concentration of the free layer pattern and a boron concentration of the oxide layer pattern is 10 at % or less, and a difference between the boron concentration of the oxide layer pattern and a boron concentration of the capping layer pattern is 10 at % or less.

This application claims priority under 35 U.S.C. § 119 from Korean Patent Application No. 10-2023-0022608, filed on Feb. 21, 2023, in the Korean Intellectual Property Office and all the benefits accruing therefrom under 35 U.S.C. 119, the contents of which in its entirety are herein incorporated by reference.

### BACKGROUND

### 1. Technical Field

The present inventive concept relates to a magnetic memory device and a method for fabricating the same.

### 2. Description of the Related Art

As electronic apparatuses become faster and lower power, memory devices equipped therein also require rapid read/write operations and a low operating voltage. A magnetic memory device is being researched as the memory device that satisfies such a requirement. The magnetic memory device is non-volatile, capable of operating at a high speed, and therefore is spotlighted as a next-generation memory.

Meanwhile, as the magnetic memory device becomes more and more highly integrated, a STT-MRAM which stores information using a spin transfer torque (STT) phenomenon is being researched. The STT-MRAM may store information by inducing magnetization reversal by directly applying a current to a magnetic tunnel junction element. Highly integrated STT-MRAM requires a high-speed operation and a low current operation.

### SUMMARY

Aspects of the present inventive concept provide a magnetic memory device having improved product reliability, performance and dispersion.

Aspects of the present inventive concept also provide a method for fabricating a magnetic memory device having improved product reliability, performance and dispersion.

However, aspects of the present inventive concept are not restricted to the ones set forth herein. The above and other aspects of the present inventive concept will become more apparent to one of ordinary skill in the art to which the present inventive concept pertains by referencing the detailed description of the present inventive concept given below.

According to aspects of the present inventive concept, there is provided a magnetic memory device comprising a pinned layer pattern, a free layer pattern including boron (B), a tunnel barrier layer pattern between the pinned layer pattern and the free layer pattern, an oxide layer pattern spaced apart from the tunnel barrier layer pattern with the free layer pattern therebetween, the oxide layer pattern including a metal borate, and a capping layer pattern spaced apart from the free layer pattern with the oxide layer pattern therebetween, the capping layer pattern including a metal boride, wherein a difference between a boron concentration of the free layer pattern and a boron concentration of the oxide layer pattern is 10 at % or less, and a difference between the boron concentration of the oxide layer pattern and a boron concentration of the capping layer pattern is 10 at % or less.

According to aspects of the present inventive concept, there is provided a magnetic memory device comprising a pinned layer pattern, a free layer pattern including at least one of cobalt (Co), iron (Fe) and nickel (Ni), and boron (B), a tunnel barrier layer pattern between the pinned layer pattern and the free layer pattern, an oxide layer pattern spaced apart from the tunnel barrier layer pattern with the free layer pattern therebetween, the oxide layer pattern including at least one of TaBO, MgBO, FeBO, CoBO, CoFeBO, IrBO, RuBO, MoBO, HfBO and ZrBO, and a capping layer pattern spaced apart from the free layer pattern with the oxide layer pattern therebetween, the capping layer pattern including at least one of TaB, MgB, CoFeB, IrB, RuB, MoB, HfB and ZrB, wherein a difference between a boron concentration of the free layer pattern and a boron concentration of the oxide layer pattern is 10 at % or less, and a difference between the boron concentration of the oxide layer pattern and a boron concentration of the capping layer pattern is 10 at % or less.

According to aspects of the present inventive concept, there is provided a magnetic memory device comprising a seed layer pattern on a substrate, a pinned layer pattern on an upper surface of the seed layer pattern, a tunnel barrier layer pattern on an upper surface of the pinned layer pattern, a free layer pattern including boron (B), on an upper surface of the tunnel barrier layer pattern, an oxide layer pattern including a metal borate, on an upper surface of the free layer pattern, and a capping layer pattern on an upper surface of the oxide layer pattern, wherein the capping layer pattern includes a first non-magnetic capping layer, a capping metal layer and a second non-magnetic capping layer that are sequentially stacked on the oxide layer pattern, each of the first non-magnetic capping layer and the second non-magnetic capping layer includes a non-magnetic metal, the capping metal layer includes a metal boride, and a difference between a boron concentration of the free layer pattern, a boron concentration of the oxide layer pattern, and a boron concentration of the capping metal layer is 10 at % or less.

According to aspects of the present inventive concept, there is provided a method for fabricating a magnetic memory device, the method comprising forming a pinned layer on a substrate, forming a tunnel barrier layer on the pinned layer, forming a free layer including boron (B) on the tunnel barrier layer, forming an oxide layer including a metal borate on the free layer, forming a capping layer including a metal boride on the oxide layer, and performing an annealing process after forming the capping layer, wherein a difference between a boron concentration of the free layer and a boron concentration of the oxide layer is 10 at % or less, and the difference between the boron concentration of the oxide layer and a boron concentration of the capping layer is 10 at % or less.

### BRIEF DESCRIPTION OF THE DRAWINGS

The above and other aspects and features of the present inventive concept will become more apparent by describing in detail exemplary embodiments thereof with reference to the attached drawings, in which:

FIG. 1 is an exemplary block diagram of a magnetic memory device according to example embodiments.

FIG. 2 is an exemplary circuit diagram for explaining a cell array of the magnetic memory device according to example embodiments.

FIG. 3 is a schematic cross-sectional view for explaining the magnetic tunnel junction element of the magnetic memory device according to example embodiments.

FIG. 4 is a schematic graph for explaining a boron (B) concentration distribution and an oxygen (O) concentration distribution of the magnetic tunnel junction element of FIG. 3.

FIG. 5A is a graph showing the switching current I_{SW} of the magnetic tunnel junction element depending on the annealing temperature.

FIG. 5B is a graph showing a coefficient of variation CV of the switching current ISW depending on the annealing temperature.

FIG. 6A is a graph showing the parallel resistance R_{P} of the magnetic tunnel junction element depending on the annealing temperature.

FIG. 6B is a graph showing the coefficient of variation CV of the parallel resistance RP depending on the annealing temperature.

FIGS. 7 to 10 are various schematic cross-sectional views for explaining the magnetic tunnel junction element of the magnetic memory device according to example embodiments.

FIG. 11 is a schematic cross-sectional view for explaining a magnetic memory device according to example embodiments.

FIGS. 12 to 20 are intermediate step diagrams for describing the method for fabricating the magnetic memory device according to example embodiments.

### DETAILED DESCRIPTION OF THE EMBODIMENTS

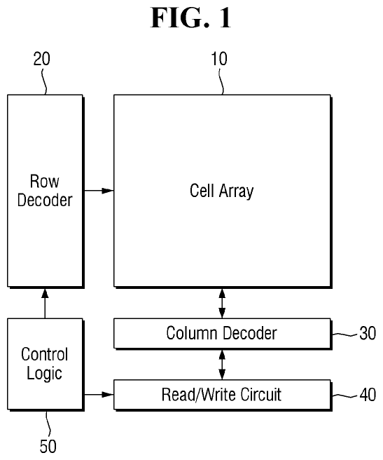

A magnetic memory device according to exemplary embodiments will be described below with reference to FIGS. 1 to 9.

FIG. 1 is an exemplary block diagram of a magnetic memory device according to example embodiments.

Referring to FIG. 1, the magnetic memory device according to some embodiments includes a cell array 10, a row decoder 20, a column decoder 30, a read/write circuit 40, and a control logic 50.

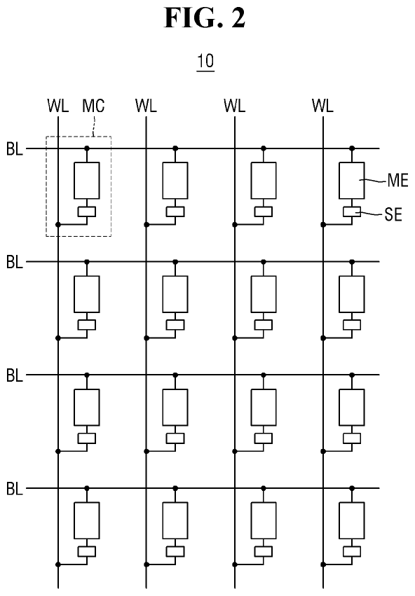

The cell array 10 may include a plurality of word lines and a plurality of bit lines. Memory cells may be connected at points on which the word lines intersect the bit lines. The cell array 10 will be described in more detail below in the description relating to FIG. 2.

The row decoder 20 may be connected to the cell array 10 through the word lines. The row decoder 20 may decode an address input from outside to select one of the plurality of word lines.

The column decoder 30 may be connected to the cell array 10 through the bit lines. The column decoder 30 may decode the address input from outside to select one of the plurality of bit lines. The bit lines selected by the column decoder 30 may be connected to the read/write circuit 40.

The read/write circuit 40 may provide bit line bias for accessing selected memory cells under the control of the control logic 50. For example, the read/write circuit 40 may provide bit line bias to selected bit lines for writing or reading the input data to the memory cells.

The control logic 50 may output control signals for controlling the magnetic memory device according to externally provided command signals. The control signals output from the control logic 50 may control the read/write circuit 40.

FIG. 2 is an exemplary circuit diagram for explaining a cell array of the magnetic memory device according to example embodiments.

Referring to FIG. 2, the cell array 10 includes a plurality of bit lines BL, a plurality of word lines WL, and a plurality of unit memory cells MC.

The word lines WL may extend in a first direction. The bit lines BL may extend in a second direction intersecting the first direction and intersect the word lines WL.

Unit memory cells MC may be arranged two-dimensionally or three-dimensionally. Each unit memory cell MC may be connected to intersection points between the word lines WL and the bit lines BL that intersect each other. Therefore, each unit memory cell MC connected to the word lines WL may be connected to the read/write circuit (e.g., read/write circuit 40 of FIG. 1) through the bit line BL. Each unit memory cell MC may include a magnetic tunnel junction element ME and a selection element SE.

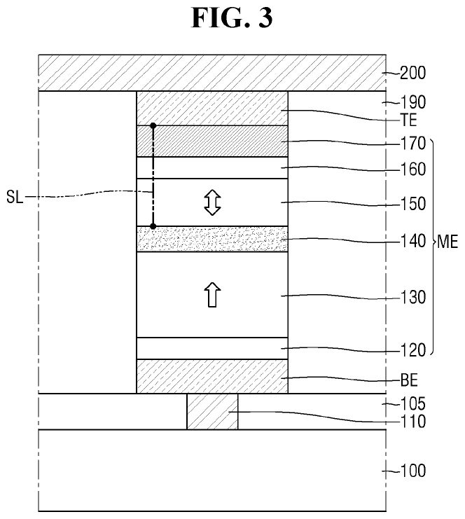

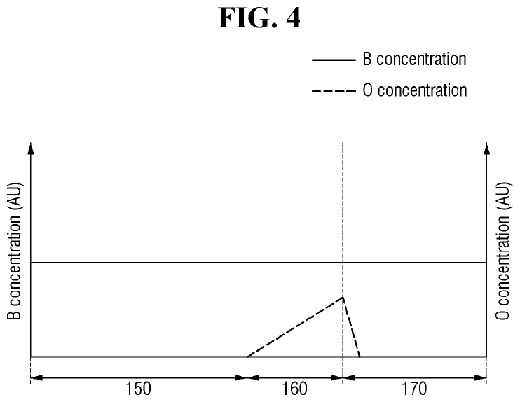

The magnetic tunnel junction element ME may be connected between the bit line BL and the selection element SE, and the selection element SE may be connected between the magnetic tunnel junction element ME and the word line WL. The magnetic tunnel junction element ME may include a pinned layer, a free layer, and a tunnel barrier layer. The magnetic tunnel junction element ME will be described below in more detail in the description relating to FIGS. 3 and 4.

The selection element SE may be configured to selectively control a flow of charge passing through the magnetic tunnel junction element ME. For example, the selection element SE may include at least one of a diode, a PNP bipolar transistor, an NPN bipolar transistor, an NMOS field effect transistor, and a PMOS field effect transistor. When the selection element SE is made up of a bipolar transistor or a MOS field effect transistor, which are three-terminal elements, additional wiring (e.g., a source line) may be connected to the selection element SE.

FIG. 3 is a schematic cross-sectional view for explaining the magnetic tunnel junction element of the magnetic memory device according to example embodiments. FIG. 4 is a schematic graph for explaining a boron (B) concentration distribution and an oxygen (O) concentration distribution of the magnetic tunnel junction element of FIG. 3.

Referring to FIGS. 3 and 4, the magnetic tunnel junction element ME of the magnetic memory device according to some embodiments includes a pinned layer pattern 130, a tunnel barrier layer pattern 140, a free layer pattern 150, an oxide layer pattern 160, and a capping layer pattern 170.

The pinned layer pattern 130 may have a fixed magnetization direction. For example, the magnetization direction of the pinned layer pattern 130 may be fixed regardless of a program current passing through it.

The pinned layer pattern 130 may include a ferromagnetic material. For example, the pinned layer pattern 130 may include, but is not limited to, at least one of an amorphous rare earth element alloy: a multi-layer thin film in which a ferromagnetic metal (FM) and a nonmagnetic metal (NM) are alternately stacked: an alloy having an Llo type crystal structure: a cobalt-based alloy: and combinations thereof.

The amorphous rare earth element alloy may include, for example, alloys such as TbFe, TbCo, TbFeCo, DyTbFeCo, and GdTbCo. The multi-layer thin film in which the ferromagnetic metal and the non-magnetic metal are alternately stacked may include, for example, multi-layer thin films such as Co/Pt, Co/Pd, CoCr/Pt, Co/Ru, Co/Os, Co/Au, and Ni/Cu. The alloy having the Llo type crystal structure may include, for example, alloys such as Fe₅₀Pt₅₀, Fe₅₀Pd₅₀, Co₅₀Pt₅₀, Fe₅₀Ni₂₀Pt₅₀, and Co₅₀Ni₂₀Pt₅₀. The cobalt-based alloy may include, for example, alloys such as CoCr, CoPt, CoCrPt, CoCrTa, CoCrPtTa, CoCrNb, and CoFeB. As an example, the pinned layer pattern 130 may be formed of and/or may include a CoFeB film.

In some embodiments, the pinned layer pattern 130 may have perpendicular magnetic anisotropy (PMA). For example, the pinned layer pattern 130 may have a magnetization easy axis in a direction perpendicular to an extending direction of the pinned layer pattern 130 (or a thickness direction of the pinned layer pattern 130, e.g., a direction perpendicular to an upper surface of the substrate 100). A unidirectional arrow of the pinned layer pattern 130 of FIG. 3 indicates that the magnetization direction of the pinned layer pattern 130 is fixed perpendicularly.

The free layer pattern 150 may have variable magnetization directions. For example, the magnetization direction of the free layer pattern 150 may be variable depending on the program current passing through it. In some embodiments, the magnetization direction of the free layer pattern 150 may be changed by a spin transfer torque (STT).

The free layer pattern 150 may include at least one magnetic element. The magnetic element of the free layer pattern 150 may include, for example, but is not limited to, at least one of cobalt (Co), iron (Fe) and nickel (Ni).

In some embodiments, the free layer pattern 150 may include at least one magnetic element and boron (B). For example, the free layer pattern 150 may include boron (B) and at least one of cobalt (Co), iron (Fe), and nickel (Ni). As an example, the free layer pattern 150 may be formed of and/or may include a CoFeB film.

In some embodiments, the free layer pattern 150 may have a boron concentration of about 10 at % to about 30 at %. In some embodiments, the boron concentration of the free layer pattern 150 may be between about 15 at % and about 25 at %.

In some embodiments, the free layer pattern 150 may have a uniform boron concentration in the thickness direction of the free layer pattern 150. In this specification, the term “uniform” means not only complete uniformity, but also minute differences that may occur due to process margins and the like.

In some other embodiments, the free layer pattern 150 may not include boron (B). As an example, the free layer pattern 150 may be formed of and/or may include a CoFe film.

In some embodiments, the free layer pattern 150 may have a perpendicular magnetic anisotropy (PMA). For example, the free layer pattern 150 may have an easy magnetization axis in a direction perpendicular to the extending direction of the free layer pattern 150 (or the thickness direction of the free layer pattern 150, e.g., in a direction perpendicular to an upper surface of the substrate 100). A double-headed arrow of the free layer pattern 150 of FIG. 3 indicates that the magnetization direction of the free layer pattern 150 may be magnetized to be parallel or antiparallel to the magnetization direction of the pinned layer pattern 130.

In some embodiments, the free layer pattern 150 may include magnetic elements that may be coupled with oxygen atoms to induce interfacial perpendicular magnetic anisotropy (i-PMA). The magnetic element may be, for example, iron (Fe). As an example, the free layer pattern 150 may be formed of and/or may include a CoFeB film or a CoFe film.

In some embodiments, the free layer pattern 150 may be amorphous. As an example, the free layer pattern 150 may be formed of and/or may include an amorphous CoFeB film or an amorphous CoFe film.

The tunnel barrier layer pattern 140 may be interposed between the pinned layer pattern 130 and the free layer pattern 150. The tunnel barrier layer pattern 140 may be provided as an insulated tunnel barrier that generates quantum mechanical tunneling between the pinned layer pattern 130 and the free layer pattern 150. In example embodiments, the tunnel barrier layer pattern 140 may contact an upper surface of the pinned layer pattern 130 and a lower surface of the free layer pattern 150.

The tunnel barrier layer pattern 140 may include, for example, but is not limited to, at least one of magnesium oxide (MgO), aluminum oxide (Al₂O₃), silicon oxide (SiO₂), tantalum oxide (Ta₂O₅), silicon nitride (SiN), aluminum nitride (AlN), and combinations thereof. For example, the tunnel barrier layer pattern 140 may include a magnesium oxide film (MgO film) having a face-centered cubic (FCC) crystal structure or a sodium chloride (NaCl) crystal structure.

The magnetic tunnel junction element ME which includes the pinned layer pattern 130, the tunnel barrier layer pattern 140, and the free layer pattern 150, may function as a variable resistance element that may switch between two resistance states by an electrical signal (e.g., program current) applied thereto. For example, when the magnetization direction of the pinned layer pattern 130 and the magnetization direction of the free layer pattern 150 are parallel (e.g., in the same direction), the magnetic tunnel junction element ME has a low resistance value, which may be stored as data “0”. In contrast, when the magnetization direction of the pinned layer pattern 130 and the magnetization direction of the free layer pattern 150 are antiparallel (e.g., in opposite directions), the magnetic tunnel junction element ME has a high resistance value, which may be stored as data “1”.

In some embodiments, the pinned layer pattern 130, the tunnel barrier layer pattern 140, and the free layer pattern 150 may be sequentially stacked on the substrate 100. The substrate 100 may be, for example, but is not limited to, a silicon substrate, a gallium arsenide substrate, a silicon germanium substrate, a ceramic substrate, a quartz substrate or a display glass substrate, or may be an SOI (Semiconductor On Insulator) substrate.

The oxide layer pattern 160 may be spaced apart from the tunnel barrier layer pattern 140 with the free layer pattern 150 therebetween. For example, the oxide layer pattern 160 may be stacked on an upper surface of the free layer pattern 150. In some embodiments, the oxide layer pattern 160 may be in contact with the free layer pattern 150.

The oxide layer pattern 160 may include a metal oxide. For example, the oxide layer pattern 160 may include tantalum (Ta), magnesium (Mg), iron (Fe), cobalt (Co), tungsten (W), iridium (Ir), ruthenium (Ru), molybdenum (Mo), hafnium (Hf), zirconium (Zr), niobium (Nb), aluminum (Al), manganese (Mn), and alloys thereof. Although the oxide layer pattern 160 is shown as a single film in FIG. 3, this is only an example, and the oxide layer pattern 160 may include multiple films including different metal oxides from each other.

The oxide layer pattern 160 may induce magnetic anisotropy at the interface with the free layer pattern 150 to improve the magnetic anisotropy of the free layer pattern 150. For example, oxygen atoms supplied from the oxide layer pattern 160 induce interfacial perpendicular magnetic anisotropy (i-PMA) at the interface with the free layer pattern 150, and may improve the perpendicular magnetic anisotropy (PMA) of the free layer pattern 150.

In some embodiments, the oxide layer pattern 160 may have an oxygen concentration gradient. For example, as shown in FIG. 4, the oxygen concentration of the oxide layer pattern 160 may decrease from the capping layer pattern 170 toward the free layer pattern 150. For example, the oxygen concentration of the oxide layer pattern 160 may be greater in a region near the capping layer pattern 170 than in a region near the free pattern layer pattern 150.

If the free layer pattern 150 includes boron (B), the oxide layer pattern 160 may further include boron (B). For example, the oxide layer pattern 160 may include metal borate. The metal borate may include, for example, at least one of TaBO, MgBO, FeBO, CoBO, CoFeBO, IrBO, RuBO, MoBO, HfBO and ZrBO. As an example, the oxide layer pattern 160 may be formed of and/or may include a TaBO film.

The oxide layer pattern 160 may have a boron concentration of a level similar to that of the free layer pattern 150. For example, as shown in FIG. 4, the boron concentration of the oxide layer pattern 160 may be equal to the boron concentration of the free layer pattern 150. In this specification, the term “same” means not only complete uniformity, but also minute differences that may occur due to process margins and the like.

In some embodiments, the difference between the boron concentration of the free layer pattern 150 and the boron concentration of the oxide layer pattern 160 may be about 10 at % or less. As an example, if the free layer pattern 150 has a boron concentration of about 20 at %, the oxide layer pattern 160 may have a boron concentration of about 10 at % to about 30 at %. When a difference between the boron concentration of the free layer pattern 150 and the boron concentration of the oxide layer pattern 160 exceeds about 10 at %, boron atoms spread between the free layer pattern 150 and the oxide layer pattern 160, and characteristics of the magnetic tunnel junction element ME may deteriorate. In some embodiments, the difference between the boron concentration of the free layer pattern 150 and the boron concentration of the oxide layer pattern 160 may be about 5 at % or less. In further embodiments, the difference between the boron concentration of the free layer pattern 150 and the boron concentration of the oxide layer pattern 160 may be about 1 at % or less.

In some embodiments, the boron concentration of the oxide layer pattern 160 may be equal to or smaller than the boron concentration of the free layer pattern 150. As an example, if the free layer pattern 150 has a boron concentration of about 20 at %, the oxide layer pattern 160 may have a boron concentration of about 10 at % to about 20 at %.

In some embodiments, the oxide layer pattern 160 may have a uniform boron concentration in the thickness direction of the oxide layer pattern 160.

If the free layer pattern 150 does not include boron (B), the oxide layer pattern 160 may also not include boron (B). For example, the oxide layer pattern 160 may include at least one of TaO, MgO, WO, IrO, RuO, MoO, HfO, and ZrO. As an example, the oxide layer pattern 160 may be formed of and/or may include a TaO layer.

The capping layer pattern 170 may be spaced apart from the free layer pattern 150 with the oxide layer pattern 160 therebetween. For example, the capping layer pattern 170 may be stacked on the upper surface of the oxide layer pattern 160. In some embodiments, the capping layer pattern 170 may be in contact with the oxide layer pattern 160.

The capping layer pattern 170 may include a metal or a metal nitride. The metal may include, for example, but is not limited to, at least one of tantalum (Ta), magnesium (Mg), tungsten (W), iridium (Ir), ruthenium (Ru), molybdenum (Mo), hafnium (Hf) and zirconium (Zr). The metal nitride may include, for example, but is not limited to, at least one of titanium nitride (TiN), tantalum nitride (TaN), aluminum nitride (AlN), zirconium nitride (ZrN), niobium nitride (NbN), molybdenum nitride (MoN), and combinations thereof. The capping layer pattern 170 may protect the magnetic tunnel junction element ME in a subsequent process after the capping layer pattern 170 is formed.

In some embodiments, a part of the capping layer pattern 170 adjacent to the oxide layer pattern 160 may include oxygen. For example, as shown in FIG. 4, the oxygen concentration of the capping layer pattern 170 adjacent to the oxide layer pattern 160 may decrease, as it goes away from the oxide layer pattern 160.

If the free layer pattern 150 includes boron (B), the capping layer pattern 170 may further include boron (B). For example, the capping layer pattern 170 may include metal boride. The metal boride may be formed of and/or may include, for example, at least one of TaB, MgB, CoFeB, IrB, RuB, MoB, HfB, and ZrB. As an example, the capping layer pattern 170 may be formed of and/or may include a TaB film.

The capping layer pattern 170 may have a boron concentration of a level similar to that of the oxide layer pattern 160. For example, as shown in FIG. 4, the boron concentration of the capping layer pattern 170 may be equal to the boron concentration of the oxide layer pattern 160.

In some embodiments, the difference between the boron concentration of the oxide layer pattern 160 and the boron concentration of the capping layer pattern 170 may be about 10 at % or less. As an example, if the oxide layer pattern 160 has a boron concentration of about 20 at %, the capping layer pattern 170 may have a boron concentration of about 10 at % to about 30 at %. If the difference between the boron concentration of the oxide layer pattern 160 and the boron concentration of the capping layer pattern 170 exceeds about 10 at %, boron atoms spread between the oxide layer pattern 160 and the capping layer pattern 170, and characteristics of the magnetic tunnel junction element ME may deteriorate. In some embodiments, the difference between the boron concentration of the oxide layer pattern 160 and the boron concentration of the capping layer pattern 170 may be about 5 at % or less. In further embodiments, the difference between the boron concentration of the oxide layer pattern 160 and the boron concentration of the capping layer pattern 170 may be about 1 at % or less.

In some embodiments, the boron concentration of the capping layer pattern 170 may be equal to or greater than the boron concentration of the oxide layer pattern 160. As an example, if the oxide layer pattern 160 has a boron concentration of about 20 at %, the capping layer pattern 170 may have a boron concentration of about 20 at % to about 30 at %.

In some embodiments, the capping layer pattern 170 may have a uniform boron concentration in the thickness direction of the capping layer pattern 170 (e.g., a direction perpendicular to an upper surface of the substrate 100).

If the free layer pattern 150 does not include boron (B), the capping layer pattern 170 may also not include boron (B). For example, the capping layer pattern 170 may include at least one of tantalum (Ta), magnesium (Mg), tungsten (W), iridium (Ir), ruthenium (Ru), molybdenum (Mo), hafnium (Hf) and zirconium (Zr). As an example, the capping layer pattern 170 may be formed of and/or may include a Ta film.

In some embodiments, the difference between the boron concentration of the free layer pattern 150, the boron concentration of the oxide layer pattern 160, and the boron concentration of the capping layer pattern 170 may be about 10 at % or less. As an example, when the free layer pattern 150 has a boron concentration of about 20 at %, the oxide layer pattern 160 and the capping layer pattern 170 may have a boron concentration of about 10 at % to about 30 at %, respectively. In some embodiments, the difference between the boron concentration of the free layer pattern 150, the boron concentration of the oxide layer pattern 160 and the boron concentration of the capping layer pattern 170 may be equal to or less than about 5 at %, and in further embodiments, equal to or less than about 1 at %.

In some embodiments, the magnetic tunnel junction element ME may further include a seed layer pattern 120. The pinned layer pattern 130 may be stacked on the upper surface of the seed layer pattern 120. The pinned layer pattern 130 may contact the upper surface of the seed layer pattern 120. The seed layer pattern 120 may be provided as a seed layer of the pinned layer pattern 130. For example, when the pinned layer pattern 130 is formed of a material having an Llo crystal structure, the seed layer pattern 120 may include conductive metal nitrides having a face-centered cubic crystal structure (FCC crystal structure or sodium chloride (NaCl) crystal structure) (e.g., titanium nitride, tantalum nitride, chromium nitride, or vanadium nitride). Alternatively, for example, if the pinned layer pattern 130 has a dense hexagonal crystal structure, the seed layer pattern 120 may include a conductive material (e.g., ruthenium) having a dense hexagonal crystal structure.

In some embodiments, the seed layer pattern 120 may include at least one of tantalum (Ta), ruthenium (Ru), titanium (Ti), palladium (Pd), platinum (Pt), magnesium (Mg), aluminum (Al), and nitrides thereof. In some embodiments, the seed layer pattern 120 may be made up of multi-layered thin films in which different non-magnetic metals are stacked. For example, the seed layer pattern 120 may include a first non-magnetic seed layer and a second non-magnetic seed layer that are sequentially stacked. The first non-magnetic seed layer may include tantalum (Ta), and the second non-magnetic seed layer may include platinum (Pt), but is not limited thereto.

The magnetic tunnel junction element ME may be connected to the selection element (e.g., selection element SE of FIG. 2) on the substrate 100. For example, a first interlayer insulating film 105, a contact plug 110, and a lower electrode pattern BE may be formed on the substrate 100.

The first interlayer insulating film 105 may cover the upper surface of the substrate 100. The first interlayer insulating film 105 may contact the upper surface of the substrate 100. The first interlayer insulating film 105 may include, for example, but is not limited to, silicon oxide, silicon oxynitride, or the like.

The contact plug 110 penetrates the first interlayer insulating film 105 and may be connected to the selection element (e.g., selection element SE of FIG. 2) on the substrate 100. The contact plug 110 may include, for example, but is not limited to, at least one of a conductive material, for example, a doped semiconductor material (e.g., doped silicon), a metal (e.g., tungsten, aluminum, copper, titanium, and/or tantalum), a conductive metal nitride (e.g., titanium nitride, tantalum nitride and/or tungsten nitride), and metal-semiconductor compounds (e.g., metal silicide).

A lower electrode pattern BE may be formed on the first interlayer insulating film 105 and the contact plug 110. The lower electrode pattern BE may contact upper surfaces of the first interlayer insulating film 105 and the contact plug 110. The lower electrode pattern BE may be electrically connected to the contact plug 110. The magnetic tunnel junction element ME may be formed on the lower electrode pattern BE. For example, the lower electrode pattern BE may be interposed between the contact plug 110 and the magnetic tunnel junction element ME. For example, the lower electrode pattern BE may contact a lower surface of the seed layer pattern 120. Accordingly, the magnetic tunnel junction element ME may be electrically connected to the selection element (e.g., selection element SE of FIG. 2) on the substrate 100. The lower electrode pattern BE may include, for example, but is not limited to, a conductive metal (e.g., titanium or tantalum) or a conductive metal nitride (e.g., titanium nitride or tantalum nitride).

The magnetic tunnel junction element ME may be connected with a conductive line 200 on the magnetic tunnel junction element ME. For example, the upper electrode pattern TE, the second interlayer insulating film 190, and the conductive line 200 may be formed on the magnetic tunnel junction element ME.

An upper electrode pattern TE may be formed on the magnetic tunnel junction element ME. For example, the upper electrode pattern TE may be stacked on an upper surface of the capping layer pattern 170. For example, the upper electrode pattern TE may contact an upper surface of the capping layer pattern 170. The upper electrode pattern TE may include, for example, but is not limited to, a conductive metal or a conductive metal nitride. For example, the upper electrode pattern TE may include at least one of ruthenium (Ru), tantalum (Ta), and nitrides thereof.

A second interlayer insulating film 190 may be formed on the first interlayer insulating film 105. The second interlayer insulating film 190 may cover the first interlayer insulating film 105, the lower electrode pattern BE, the magnetic tunnel junction element ME, and the upper electrode pattern TE. For example, the second interlayer insulating film 190 may contact an upper surface of the first interlayer insulating film 105 and side surfaces of the lower electrode pattern BE, the seed layer pattern 120, the pinned layer pattern 130, the tunnel barrier layer pattern 140, the free layer pattern 150, the oxide layer pattern 160, the capping layer pattern 170, and the upper electrode pattern TE. The second interlayer insulating film 190 may include, for example, but is not limited to, silicon oxide, silicon oxynitride or the like.

The conductive line 200 may be formed on the second interlayer insulating film 190 and the upper electrode pattern TE. For example, the conductive line 200 may contact upper surfaces of the upper electrode pattern TE and the second interlayer insulating film 190. The conductive line 200 may be electrically connected to the upper electrode pattern TE. For example, the upper electrode pattern TE may be interposed between the magnetic tunnel junction element ME and the conductive line 200. Accordingly, the magnetic tunnel junction element ME may be electrically connected to the conductive line 200. In some embodiments, the conductive line 200 may be provided as a bit line BL of FIG. 2.

An amorphous magnetic material containing boron (B) may be used as the free layer of the magnetic tunnel junction element. However, in a high-temperature process for fabricating a magnetic memory device including the magnetic tunnel junction element, there is a problem that boron atoms contained in the free layer spread into adjacent layers, and deteriorate the characteristics of the magnetic memory device. For example, in a high temperature process such as a heat treatment process and/or post-process (or Back End Of Line (BEOL)), boron atoms of the free layer may spread toward an oxide layer and/or a capping layer stacked on the free layer. Accordingly, the amorphous magnetic material of the free layer may change to a crystalline material, or excess oxygen of the oxide layer may flow into the free layer from which boron leaves, thereby deteriorating the dispersion of the magnetic memory device.

However, in the magnetic memory device according to example embodiments, since the magnetic tunnel junction element ME includes the free layer pattern 150, the oxide layer pattern 160, and the capping layer pattern 170, it is possible to prevent the boron atoms contained in the free layer pattern 150 from spreading. Specifically, as explained above, since the free layer pattern 150, the oxide layer pattern 160, and the capping layer pattern 170 have boron concentrations of the same as or similar levels to each other, it is possible to minimize spread of boron atoms depending on the boron concentration gradient. Accordingly, it is possible to provide a magnetic memory device in which dispersion is improved and product reliability and performance are enhanced.

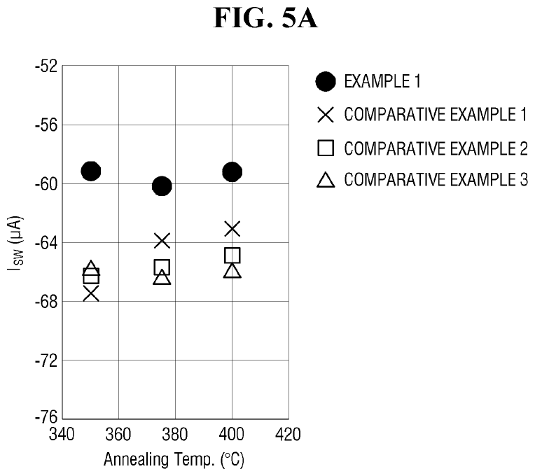

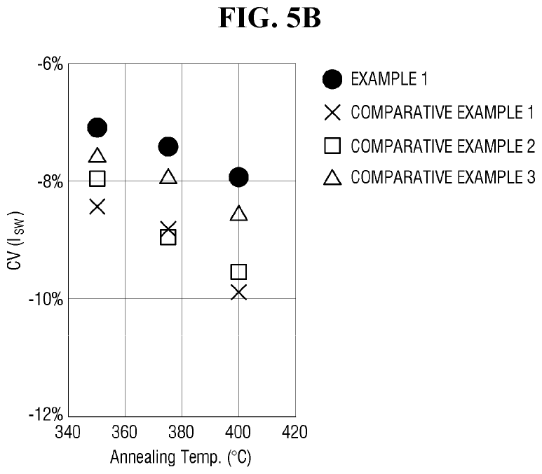

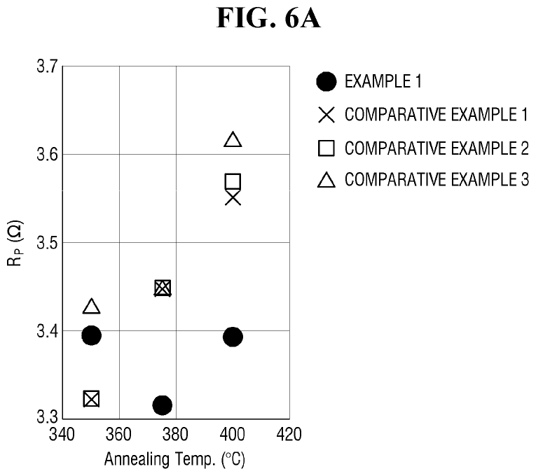

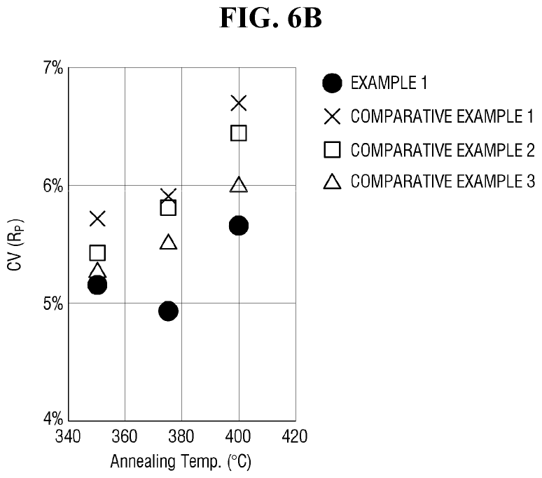

Hereinafter, effects of the magnetic memory device according to some embodiments will be described with reference to Example 1, Comparative Examples 1 to 3, and FIGS. 5A to 6B.

### EXAMPLE 1

The magnetic tunnel junction element was fabricated, using CoFeB film as a pinned layer pattern, an MgO film as a tunnel barrier layer pattern, a CoFeB film containing about 19 at % of boron (B) as a free layer pattern, a TaBO film containing about 19 at % of boron (B) as an oxide layer pattern (e.g., oxide layer pattern 160), and a TaB film containing about 19 at % of boron (B) as a capping layer pattern (e.g., capping layer pattern 170).

### Comparative Example 1

The magnetic tunnel junction element was fabricated in the manner similar to Example 1, except that a TaO film was used as the oxide layer pattern.

### Comparative Example 2

The magnetic tunnel junction element was fabricated in the manner similar to Example 1 above, except that a double film of Ta/TaB was used as the oxide layer pattern in Example 1 above.

### Comparative Example 3

The magnetic tunnel junction element was fabricated in the manner similar to Example 1 above, except that a double film of Ta/CoFeB was used as the oxide layer pattern in Example 1 above.

Next, an annealing temperature was changed, and a switching current I_{SW} and a parallel resistance R_{P} of the magnetic tunnel junction elements according to Example 1 and Comparative Examples 1 to 3 were measured and shown in FIGS. 5A to 6B. Specifically, FIG. 5A is a graph showing the switching current I_{SW} of the magnetic tunnel junction element depending on the annealing temperature. FIG. 5B is a graph showing a coefficient of variation CV of the switching current ISW depending on the annealing temperature. FIG. 6A is a graph showing the parallel resistance R_{P} of the magnetic tunnel junction element depending on the annealing temperature. FIG. 6B is a graph showing the coefficient of variation CV of the parallel resistance RP depending on the annealing temperature.

Referring to FIGS. 5A and 6A, unlike the magnetic tunnel junction elements of Comparative Examples 1 to 3, in which all or part of the oxide layer pattern does not include boron, it may be seen that the magnetic tunnel junction element of Example 1 has relatively uniform switching current I_{SW} and parallel resistance R_{P} at a wide range of annealing temperatures (350° C. to 400° C.). Also, referring to FIGS. 5B and 6B, it may be seen that the magnetic tunnel junction element according to Example 1 exhibits a relatively low coefficient of variation CV even at an increased annealing temperature. Accordingly, it may be confirmed that the magnetic tunnel junction element according to Example 1 exhibits improved dispersion compared to Comparative Examples 1 to 3.

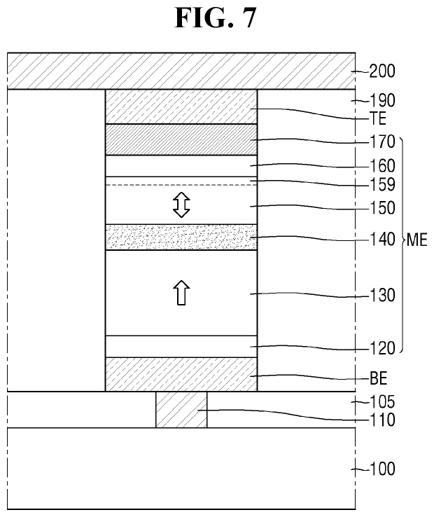

FIGS. 7 to 10 are various schematic cross-sectional views for explaining the magnetic tunnel junction element ME of the magnetic memory device according to some embodiments. For convenience of explanation, repeated description of contents explained above using FIGS. 1 to 4 will be briefly explained or omitted.

Referring to FIG. 7, in the magnetic memory device according to example embodiments, the magnetic tunnel junction element ME further includes an interfacial layer 159

The interfacial layer 159 may be interposed between the free layer pattern 150 and the oxide layer pattern 160. The interfacial layer 159 may be formed by combining a part of the free layer pattern 150 adjacent to the oxide layer pattern 160 with oxygen atoms supplied from the oxide layer pattern 160. The interfacial layer 159 may induce perpendicular magnetic anisotropy (i-PMA) to improve the perpendicular magnetic anisotropy (PMA) of the free layer pattern 150. In some embodiments, the interfacial layer 159 may include iron-oxygen (Fe-O) bonds.

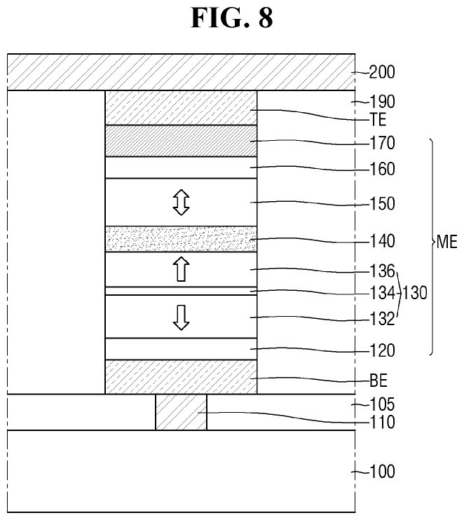

Referring to FIG. 8, in the magnetic memory device according to example embodiments, the pinned layer pattern 130 includes synthetic anti-ferromagnet (SAF).

For example, the pinned layer pattern 130 may include a first sub-pinned layer 132, an anti-ferromagnetic coupling layer 134, and a second sub-pinned layer 136 that are sequentially stacked on the seed layer pattern 120. The pinned layer pattern 130 may exhibit, for example, anti-ferromagnetic coupling (AFC) characteristics due to RKKY (Ruderman-Kittel-Kasuya-Yosida) interaction. For example, as shown, the magnetization directions of the first sub-pinned layer 132 and the magnetization directions of the second sub-pinned layer 136 are aligned antiparallel to minimize the total amount of magnetization of the pinned layer pattern 130. Since the first sub-pinned layer 132 and the second sub-pinned layer 136 constitute the pinned layer pattern 130, they may have a fixed magnetization direction.

The first sub-pinned layer 132 and the second sub-pinned layer 136 may each include a ferromagnetic material. For example, the first sub-pinned layer 132 and the second sub-pinned layer 136 may include at least one of an amorphous rare earth element alloy, multi-layer thin films in which a ferromagnetic metal (FM) and a nonmagnetic metal (NM) are alternately stacked, alloys having an Llo type crystal structure, cobalt-based alloys, and combinations thereof.

The anti-ferromagnetic coupling layer 134 may be interposed between the first sub-pinned layer 132 and the second sub-pinned layer 136. The first sub-pinned layer 132 and the second sub-pinned layer 136 may form an anti-ferromagnetic coupling (AFC) via the anti-ferromagnetic coupling layer 134. The anti-ferromagnetic coupling layer 134 may include a nonmagnetic material, for example, but is not limited to, at least one of ruthenium (Ru), chromium (Cr), platinum (Pt), palladium (Pd), iridium (Ir), rhodium (Rh), osmium (Os), rhenium (Re), gold (Au), copper (Cu), and combinations thereof.

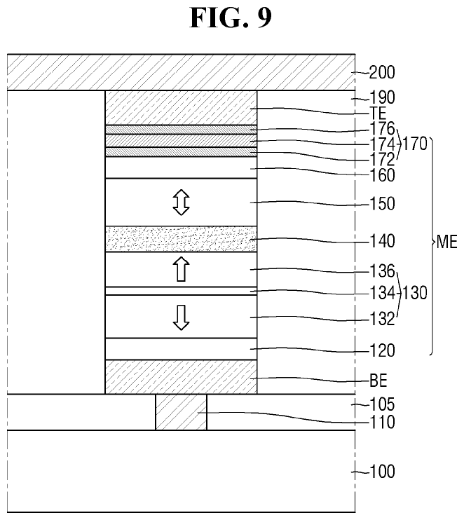

Referring to FIG. 9, in the magnetic memory device according to example embodiments, the capping layer pattern 170 is formed of multiple layers. For example, the capping layer pattern 170 may include a first non-magnetic capping layer 172, a capping metal layer 174, and a second non-magnetic capping layer 176 that are sequentially stacked on the oxide layer pattern 160.

The first non-magnetic capping layer 172 and the second non-magnetic capping layer 176 may each include a non-magnetic metal. The non-magnetic metal may include, for example, ruthenium (Ru) or molybdenum (Mo). As an example, the first non-magnetic capping layer 172 and the second non-magnetic capping layer 176 may each include a Ru film.

The capping metal layer 174 may be interposed between the first non-magnetic capping layer 172 and the second non-magnetic capping layer 176. The capping metal layer 174 may include a metal or metal nitride. The metal may include, for example, but is not limited to, at least one of tantalum (Ta), magnesium (Mg), tungsten (W), iridium (Ir), ruthenium (Ru), molybdenum (Mo), hafnium (Hf), and zirconium (Zr). The metal nitride may include, for example, but is not limited to, titanium nitride (TiN), tantalum nitride (TaN), aluminum nitride (AlN), zirconium nitride (ZrN), niobium nitride (NbN), molybdenum nitride (MoN), and combinations thereof.

When the free layer pattern 150 includes boron (B), the capping metal layer 174 may further include boron (B). For example, the capping metal layer 174 may include a metal boride. The metal boride may include, for example, at least one of TaB, MgB, CoFeB, IrB, RuB, MoB, HfB, and ZrB.

The capping metal layer 174 may have a boron concentration of a level the same as or similar to that of the oxide layer pattern 160. For example, the boron concentration of the capping metal layer 174 may be equal to the boron concentration of the oxide layer pattern 160. In some embodiments, the difference between the boron concentration of the oxide layer pattern 160 and the boron concentration of the capping metal layer 174 may be about 10 at % or less. In some embodiments, the difference between the boron concentration of the oxide layer pattern 160 and the boron concentration of the capping metal layer 174 may be about 5 at % or less, and in further embodiments, about 1 at % or less.

In some embodiments, the difference between the boron concentration of the free layer pattern 150, the boron concentration of the oxide layer pattern 160, and the boron concentration of the capping metal layer 174 may be about 10 at % or less. In some embodiments, the difference between the boron concentration of the free layer pattern 150, the boron concentration of the oxide layer pattern 160 and the boron concentration of the capping metal layer 174 may be about 5 at % or less, and in further embodiments, about 1 at % or less.

In some embodiments, when the capping metal layer 174 includes a metal boride, the first non-magnetic capping layer 172 and the second non-magnetic capping layer 176 may further include boron (B). For example, boron atoms in the capping metal layer 174 may spread into the first non-magnetic capping layer 172 and the second non-magnetic capping layer 176.

If the free layer pattern 150 does not include boron (B), the capping metal layer 174 may also include no boron (B). For example, the capping metal layer 174 may include at least one of tantalum (Ta), magnesium (Mg), tungsten (W), iridium (Ir), ruthenium (Ru), molybdenum (Mo), hafnium (Hf), and zirconium (Zr).

In some embodiments, the pinned layer pattern 130 may include a first sub-pinned layer 132, an anti-ferromagnetic coupling layer 134, and a second sub-pinned layer 136 that are sequentially stacked on the seed layer pattern 120.

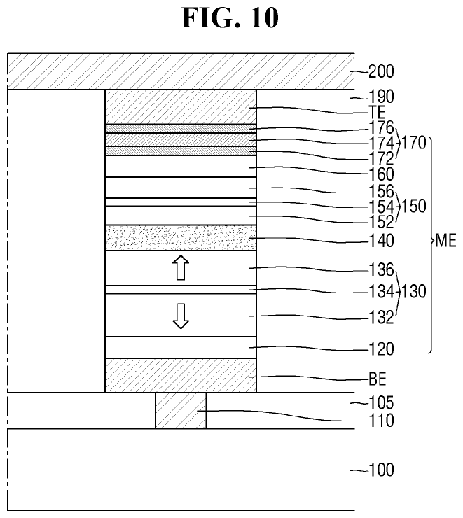

Referring to FIG. 10, in the magnetic memory device according to example embodiments, the free layer pattern 150 is formed of multiple layers. For example, the free layer pattern 150 may include a first sub-free layer 152, an insertion layer 154, and a second sub-free layer 156 that are sequentially stacked on the tunnel barrier layer pattern 140.

The first sub-free layer 152 and the second sub-free layer 156 may each include at least one magnetic element. The magnetic element may include, for example, but is not limited to, at least one of cobalt (Co), iron (Fe) and nickel (Ni).

In some embodiments, the first sub-free layer 152 and the second sub-free layer 156 may each include at least one of the magnetic elements and boron (B). For example, the first sub-free layer 152 and the second sub-free layer 156 may each include at least one of cobalt (Co), iron (Fe) and nickel (Ni), and boron (B). As an example, the first sub-free layer 152 and the second sub-free layer 156 may each include a CoFeB film.

The insertion layer 154 may be interposed between the first sub-free layer 152 and the second sub-free layer 156. The insertion layer 154 may attract the boron atoms in the first sub-free layer 152 and the second sub-free layer 156 from leaving the free layer pattern 150. For example, the insertion layer 154 may have a boron affinity greater than the first sub-free layer 152 and the second sub-free layer 156. The insertion layer 154 may include, for example, but is not limited to, at least one of molybdenum (Mo), tungsten (W), tantalum (Ta), hafnium (Hf), cobalt iron molybdenum (CoFeMo), magnesium (Mg), and alloys thereof.

In some embodiments, the pinned layer pattern 130 may include a first sub-pinned layer 132, an anti-ferromagnetic coupling layer 134, and a second sub-pinned layer 136 that are sequentially stacked on the seed layer pattern 120.

In some embodiments, the capping layer pattern 170 may include a first non-magnetic capping layer 172, a capping metal layer 174, and a second non-magnetic capping layer 176 that are sequentially stacked on the oxide layer pattern 160.

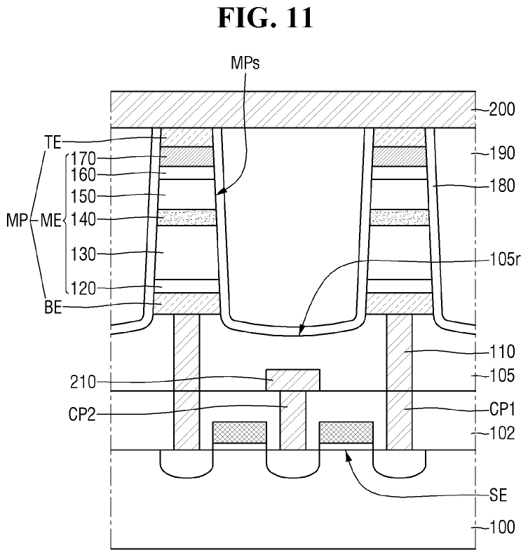

FIG. 11 is a schematic cross-sectional view for explaining a magnetic memory device according to example embodiments. For convenience of explanation, repeated description of contents explained above using FIGS. 1 to 10 will be briefly explained or omitted.

Referring to FIG. 11, the magnetic memory device according to some embodiments includes a selection element SE, a source line 210, a plurality of memory cells MP, and a conductive line 200.

The selection element SE may be formed on the substrate 100. Although the selection element SE is shown as being a MOS field effect transistor, this is exemplary only. As another example, a diode or a bipolar transistor may constitute the selection element SE.

The source line 210 may be formed on the substrate 100. The source line 210 may be electrically connected to the selection element SE. For example, a third interlayer insulating film 102 which cover the selection element SE may be formed on the substrate 100. The source line 210 may be formed on the third interlayer insulating film 102. Also, a source contact CP2 which penetrates the third interlayer insulating film 102 to connect the selection element SE and the source line 210 may be formed. Although two adjacent selection elements SE are shown to share one source line 210, this is merely an example. As another example, it goes without saying that the source line 210 corresponding to each of the selection elements SE may be provided.

A plurality of memory cells MP may be formed on the substrate 100. Each memory cell MP may be electrically connected to the selection element SE. For example, a first interlayer insulating film 105 which covers the source line 210 may be formed on the third interlayer insulating film 102. The memory cells MP may be formed on the first interlayer insulating film 105. Also, a landing contact CP1 which penetrates the third interlayer insulating film 102 may be formed, and a contact plug 110 which penetrates the first interlayer insulating film 105 to connect the landing contact CP1 and each memory cell MP may be formed.

Each memory cell MP may include a lower electrode pattern BE, a magnetic tunnel junction element ME, and an upper electrode pattern TE. The magnetic tunnel junction element ME may include at least one of the magnetic tunnel junction elements ME explained above using FIGS. 1 to 10. As an example, the magnetic tunnel junction element ME may include the seed layer pattern 120, the pinned layer pattern 130, the tunnel barrier layer pattern 140, the free layer pattern 150, the oxide layer pattern 160 and the capping layer pattern 170 explained above using FIG. 3.

In some embodiments, a capping liner 180 which covers each memory cell MP may be formed. For example, the capping liner 180 may conformally extend along the profile of the upper surface of the first interlayer insulating film 105 and the profile of the side surface of each memory cell MP. A second interlayer insulating film 190 may be stacked on the capping liner 180.

The capping liner 180 may be provided as a protective layer that protects the memory cell MP from moisture or oxidation. For example, the capping liner 180 may prevent the properties of the magnetic tunnel junction element ME (e.g., retention, coercivity (Hc), resistance-area multiplication (RA), TMR ratio (Tunneling Magnetoresistance ratio), etc.) from degrading due to moisture or oxidation. The capping liner 180 may include, for example, but is not limited to, a silicon nitride film.

In some embodiments, the upper surface of the first interlayer insulating film 105 may include a recess 105r. The recess 105r may be formed in the first interlayer insulating film 105 between the memory cells MP. The recess 105r may be formed by removing a part of the upper portion of the first interlayer insulating film 105 in the process of patterning of the memory cell MP. In some embodiments, a part of the capping liner 180 may extend along the recess 105r.

A conductive line 200 may be formed on the second interlayer insulating film 190 and the memory cell MP. The conductive line 200 may be electrically connected to a plurality of memory cells MP arranged along the direction in which conductive line 200 extends. In some embodiments, the conductive line 200 may be provided as the bit line BL of FIG. 2.

A method for fabricating a magnetic memory device according to exemplary embodiments will be described below with reference to FIGS. 1 to 20.

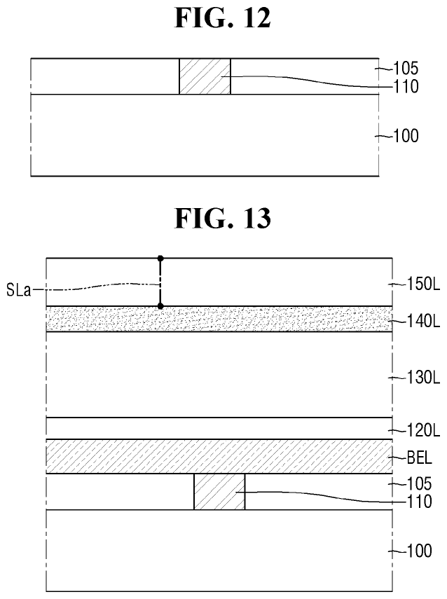

FIGS. 12 to 20 are intermediate step diagrams for describing the method for fabricating the magnetic memory device according to example embodiments. For convenience of explanation, repeated description of contents explained above using FIGS. 1 to 11 will be briefly explained or omitted.

Referring to FIG. 12, the first interlayer insulating film 105 and the contact plug 110 are formed on the substrate 100.

For example, the first interlayer insulating film 105 may be formed on the substrate 100. Subsequently, a contact plug 110 which penetrates the first interlayer insulating film 105 and is connected to a selection element (e.g., selection element SE of FIG. 2) on the substrate 100 may be formed.

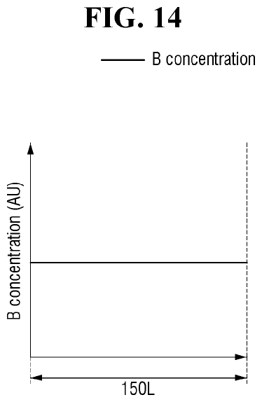

Referring to FIGS. 13 and 14, a lower electrode layer BEL, a seed layer 120L, a pinned layer 130L, a tunnel barrier layer 140L and a free layer 150L are formed on the first interlayer insulating film 105 and the contact plug 110. For reference, FIG. 14 is a schematic graph for explaining the boron (B) concentration distribution along a line SLa of FIG. 13.

For example, a lower electrode layer BEL connected to the contact plug 110 may be formed on the first interlayer insulating film 105. The seed layer 120L, the pinned layer 130L, the tunnel barrier layer 140L, and the free layer 150L may be sequentially stacked on the lower electrode layer BEL. The pinned layer 130L, the tunnel barrier layer 140L, and the free layer 150L may correspond to the pinned layer pattern 130, the tunnel barrier layer pattern 140, and the free layer pattern 150 explained above using FIGS. 3 and 4, respectively. As an example, the pinned layer pattern 130 may include a CoFeB film, the tunnel barrier layer pattern 140 may include an MgO film, and the free layer pattern 150 may include a CoFeB film.

The pinned layer 130L, the tunnel barrier layer 140L, and the free layer 150L may each be formed by, but are not limited to, a physical vapor deposition (PVD) (e.g., a sputtering process), a chemical vapor deposition (CVD) process, or an atomic layer deposition (ALD) process.

In some embodiments, the free layer 150L may include boron (B), as shown in FIG. 14. For example, the free layer 150L may include boron (B) and at least one of cobalt (Co), iron (Fe), and nickel (Ni). In some embodiments, the free layer 150L may have a uniform boron concentration in the thickness direction of the free layer 150L (e.g., a direction perpendicular to an upper surface of the substrate 100). In some embodiments, the free layer 150L may have a boron concentration of about 10 at % to about 30 at %. In some embodiments, the free layer 150L may have a boron concentration of about 15 at % to about 25 at %.

In some other embodiments, the free layer 150L may not include boron (B).

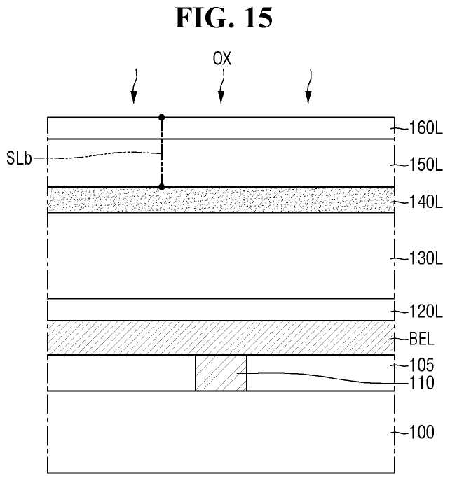

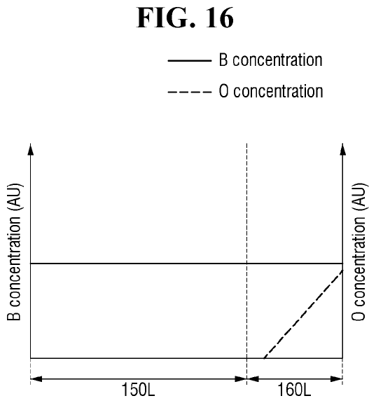

Referring to FIGS. 15 and 16, an oxide layer 160L is formed on the free layer 150L. For reference, FIG. 16 is a schematic graph for explaining the boron (B) concentration distribution and oxygen (O) concentration distribution along a line SLb of FIG. 15.

For example, a preliminary oxidation layer is formed on the free layer 150L. The preliminary oxidation layer may include metal. For example, the preliminary oxidation layer may include at least one of tantalum (Ta), magnesium (Mg), iron (Fe), cobalt (Co), tungsten (W), iridium (Ir), ruthenium (Ru), molybdenum (Mo), hafnium (Hf), zirconium (Zr), niobium (Nb), aluminum (Al), manganese (Mn), and alloys thereof. Next, an oxidation process (OX) is performed on the preliminary oxidation layer. Therefore, the oxide layer 160L containing a metal oxide may be formed.

In some embodiments, the oxide layer 160L may have an oxygen concentration gradient. For example, as shown in FIG. 16, the oxygen concentration of the oxide layer 160L may decrease toward the free layer 150L. This may be due to the fact that the oxidation process (OX) is performed on the upper surface of the preliminary oxidation layer.

If the free layer 150L includes boron (B), the oxide layer 160L may further include boron (B). For example, the preliminary oxidation layer may include metal boride. The metal boride may include, for example, at least one of TaB, MgB, FeB, CoB, CoFeB, IrB, RuB, MoB, HfB and ZrB. As the oxidation process (OX) is performed on the preliminary oxidation layer including the metal boride, the oxide layer 160L including metal borate may be formed.

The oxide layer 160L may have a boron concentration of a level similar to that of the free layer 150L. For example, as shown in FIG. 16, the boron concentration of the oxide layer 160L may be the same as the boron concentration of the free layer 150L. In some embodiments, a difference between the boron concentration of the free layer 150L and the boron concentration of the oxidized layer 160L may be about 10 at % or less. In some embodiments, the difference between the boron concentration of the free layer 150L and the boron concentration of the oxidized layer 160L may be about 5 at % or less, and in further embodiments, about 1 at % or less. In some embodiments, the oxide layer 160L may have a uniform boron concentration in the thickness direction of the oxide layer 160L.

If the free layer 150L does not include boron (B), the oxide layer 160L may also include no boron (B).

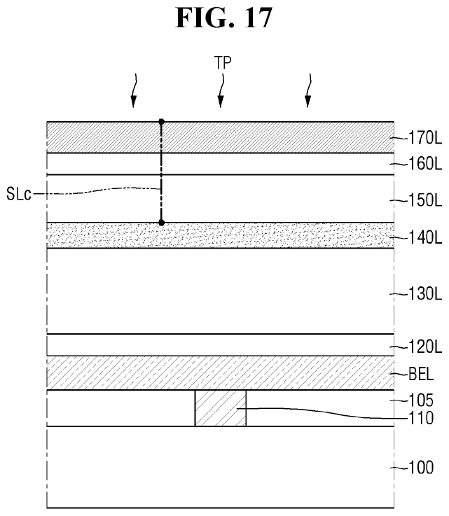

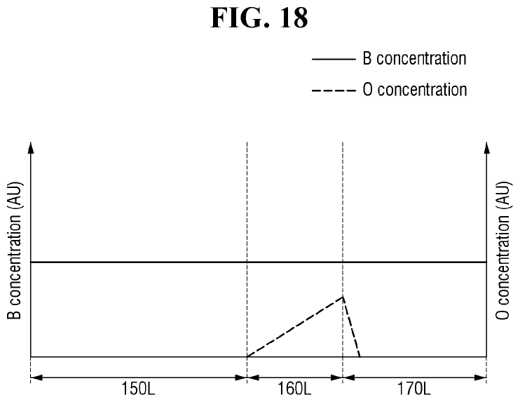

Referring to FIGS. 17 and 18, the capping layer 170L is formed on the oxide layer 160L. For reference, FIG. 18 is a schematic graph for explaining the boron (B) concentration distribution and the oxygen (O) concentration distribution along a line SLc of FIG. 17.

The capping layer 170L may include a metal or metal nitride. The metal may include, for example, but is not limited to, at least one of tantalum (Ta), magnesium (Mg), tungsten (W), iridium (Ir), ruthenium (Ru), molybdenum (Mo), hafnium (Hf), and zirconium (Zr). The metal nitride may include, for example, but is not limited to, at least one of titanium nitride (TiN), tantalum nitride (TaN), aluminum nitride (AlN), zirconium nitride (ZrN), niobium nitride (NbN), molybdenum nitride (MoN), and combinations thereof.

When the free layer 150L includes boron (B), the capping layer 170L may further include boron (B). For example, the capping layer 170L may include a metal boride. The metal boride may include, for example, at least one of TaB, MgB, CoFeB, IrB, RuB, MoB, HfB, and ZrB.

The capping layer 170L may have a boron concentration of a level the same as or similar to that of the oxide layer 160L. For example, as shown in FIG. 18, the boron concentration of the capping layer 170L may be equal to the boron concentration of the oxide layer 160L. In some embodiments, the difference between the boron concentration of the oxide layer 160L and the boron concentration of the capping layer 170L may be about 10 at % or less. In some embodiments, a difference between the boron concentration of the oxide layer 160L and the boron concentration of the capping layer 170L may be about 5 at % or less, and in further embodiments, about 1 at % or less. In some embodiments, the capping layer 170L may have a uniform boron concentration in the thickness direction of the capping layer 170L.

When the free layer 150L does not include boron (B), the capping layer 170L may also include no boron (B).

In some embodiments, the difference between the boron concentration of the free layer 150L, the boron concentration of the oxidized layer 160L, and the boron concentration of the capping layer 170L may be about 10 at % or less. In some embodiments, the difference between the boron concentration of the free layer 150L, the boron concentration of the oxidized layer 160L and the boron concentration of the capping layer 170L may be about 5 at % or less, and in further embodiments, about 1 at % or less.

After forming the capping layer 170L, an annealing process (TP) may be performed. The annealing process (TP) may be performed at, for example, 350° C. to 400° C., but is not limited thereto. As noted above, when the free layer 150L, the oxide layer 160L, and the capping layer 170L have boron concentrations of the same or similar levels to each other, spread of boron atoms due to the annealing process (TP) may be minimized. As a result, it is possible to provide a method for fabricating a magnetic memory device having improved dispersion and enhanced product reliability and performance.

In some embodiments, as the annealing process (TP) is performed, the oxygen atoms contained in the oxide layer 160L may spread into the capping layer 170L. For example, as shown in FIG. 18, a part of the capping layer 170L adjacent to the oxide layer 160L may include oxygen. Also, the oxygen concentration of the capping layer 170L adjacent to the oxide layer 160L may decrease, as it goes away from the oxide layer 160L. Although FIG. 18 only shows that the free layer 150L adjacent to the oxide layer 160L does not include oxygen, this is merely an example. As another example, a part of the free layer 150L adjacent to the oxide layer 160L may include oxygen. Also, the oxygen concentration of the free layer 150L adjacent to the oxide layer 160L may decrease as it goes away from the oxide layer 160L.

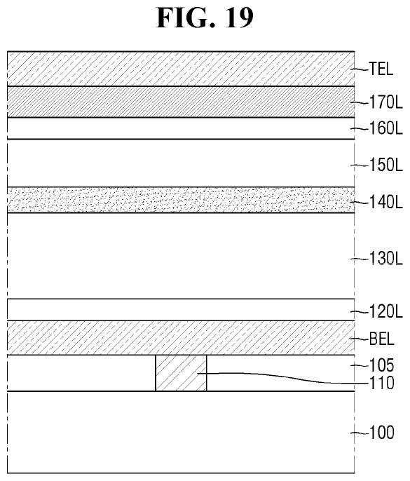

Referring to FIG. 19, an upper electrode layer TEL is formed on the capping layer 170L.

The upper electrode layer TEL may include, for example, but is not limited to, a conductive metal or a conductive metal nitride. For example, the upper electrode layer TEL may include at least one of ruthenium (Ru), tantalum (Ta), and nitrides thereof.

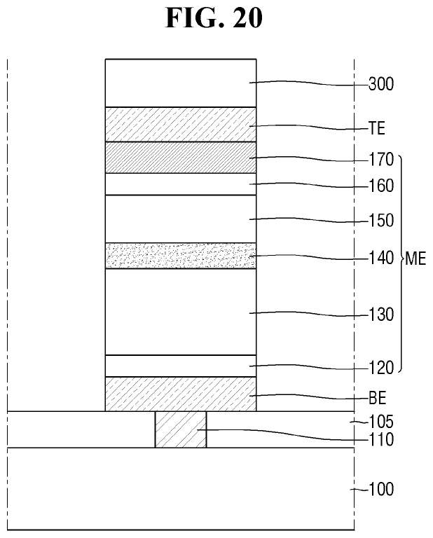

Referring to FIG. 20, a lower electrode pattern BE, a magnetic tunnel junction element ME and an upper electrode pattern TE are formed.

For example, a mask pattern 300 may be formed on the upper electrode layer TEL of FIG. 19. After that, an etching process of using the mask pattern 300 as an etching mask may be performed. As the etching process is performed, the lower electrode layer BEL, the seed layer 120L, the pinned layer 130L, the tunnel barrier layer 140L, the free layer 150L, the oxide layer 160L, the capping layer 170L and the upper electrode layer TEL of FIG. 19 may be patterned. Thus, the lower electrode pattern BE, the seed layer pattern 120, the pinned layer pattern 130, the tunnel barrier layer pattern 140, the free layer pattern 150, the oxide layer pattern 160, the capping layer pattern 170, and the upper electrode pattern TE may be formed.

Next, referring to FIG. 3, a second interlayer insulating film 190 and a conductive line 200 are formed. The magnetic memory device explained above using FIGS. 3 and 4 may be fabricated accordingly.

While the present inventive concept has been particularly shown and described with reference to exemplary embodiments thereof, it will be understood by those of ordinary skill in the art that various changes in form and details may be made therein without departing from the spirit and scope of the present inventive concept. It is therefore desired that the present embodiments be considered in all respects as illustrative and not restrictive, reference being made to the appended claims rather than the foregoing description to indicate the scope of the invention.

1. A magnetic memory device comprising:
a pinned layer pattern;
a free layer pattern including boron (B);
a tunnel barrier layer pattern between the pinned layer pattern and the free layer pattern;
an oxide layer pattern spaced apart from the tunnel barrier layer pattern with the free layer pattern therebetween, the oxide layer pattern including a metal borate; and
a capping layer pattern spaced apart from the free layer pattern with the oxide layer pattern therebetween, the capping layer pattern including a metal boride,
wherein a difference between a boron concentration of the free layer pattern and a boron concentration of the oxide layer pattern is 10 at % or less, and
wherein a difference between the boron concentration of the oxide layer pattern and a boron concentration of the capping layer pattern is 10 at % or less.

2. The magnetic memory device of claim 1,
wherein the boron concentration of the free layer pattern is 10 to 30 at %.

3. The magnetic memory device of claim 1,
wherein the boron concentration of the oxide layer pattern is equal to or smaller than the boron concentration of the free layer pattern.

4. The magnetic memory device of claim 1,
wherein an oxygen concentration of the oxide layer pattern decreases from the capping layer pattern toward the free layer pattern.

5. The magnetic memory device of claim 1,
wherein the boron concentration of the capping layer pattern is equal to or greater than the boron concentration of the oxide layer pattern.

6. The magnetic memory device of claim 1,
wherein the capping layer pattern includes a first non-magnetic capping layer, a capping metal layer, and a second non-magnetic capping layer which are sequentially stacked on the oxide layer pattern,
wherein the first non-magnetic capping layer and the second non-magnetic capping layer each include a non-magnetic metal, and
wherein the capping metal layer includes the metal boride.

7. The magnetic memory device of claim 1,
wherein the pinned layer pattern comprises synthetic anti-ferromagnet (SAF).

8. The magnetic memory device of claim 1,
wherein the free layer pattern further comprises at least one of cobalt (Co), iron (Fe), and nickel (Ni).

9. The magnetic memory device of claim 1,
wherein the metal borate comprises at least one of TaBO, MgBO, FeBO, CoBO, CoFeBO, IrBO, RuBO, MoBO, HfBO, and ZrBO.

10. The magnetic memory device of claim 1,
wherein the metal boride comprises at least one of TaB, MgB, CoFeB, IrB, RuB, MoB, HfB, and ZrB.

11. A magnetic memory device comprising:
a pinned layer pattern;
a free layer pattern including boron (B) and at least one of cobalt (Co), iron (Fe) and nickel (Ni);
a tunnel barrier layer pattern between the pinned layer pattern and the free layer pattern;
an oxide layer pattern spaced apart from the tunnel barrier layer pattern with the free layer pattern therebetween, the oxide layer pattern including at least one of TaBO, MgBO, FeBO, CoBO, CoFeBO, IrBO, RuBO, MoBO, HfBO, and ZrBO; and
a capping layer pattern spaced apart from the free layer pattern with the oxide layer pattern therebetween, the capping layer pattern including at least one of TaB, MgB, CoFeB, IrB, RuB, MoB, HfB, and ZrB,
wherein a difference between a boron concentration of the free layer pattern and a boron concentration of the oxide layer pattern is 10 at % or less, and
wherein a difference between the boron concentration of the oxide layer pattern and a boron concentration of the capping layer pattern is 10 at % or less.

12. The magnetic memory device of claim 11,
wherein the difference between the boron concentration of the free layer pattern and the boron concentration of the oxide layer pattern is 5 at % or less, and
wherein the difference between the boron concentration of the oxide layer pattern and the boron concentration of the capping layer pattern is 5 at % or less.

13. The magnetic memory device of claim 12,
wherein the difference between the boron concentration of the free layer pattern and the boron concentration of the oxide layer pattern is 1 at % or less, and
wherein the difference between the boron concentration of the oxide layer pattern and the boron concentration of the capping layer pattern is 1 at % or less.

14. The magnetic memory device of claim 11,
wherein the boron concentration of the oxide layer pattern is equal to or smaller than the boron concentration of the free layer pattern.

15. The magnetic memory device of claim 11,
wherein the boron concentration of the capping layer pattern is equal to or greater than the boron concentration of the oxide layer pattern.

16. (canceled)

17. The magnetic memory device of claim 11,
wherein the free layer pattern comprises a CoFeB film,
wherein the oxide layer pattern comprises a TaBO film, and
wherein the capping layer pattern comprises a TaB film.

18. A magnetic memory device comprising:
a seed layer pattern on a substrate;
a pinned layer pattern on an upper surface of the seed layer pattern;
a tunnel barrier layer pattern on an upper surface of the pinned layer pattern;
a free layer pattern including boron (B), on an upper surface of the tunnel barrier layer pattern;
an oxide layer pattern including a metal borate, on an upper surface of the free layer pattern; and
a capping layer pattern on an upper surface of the oxide layer pattern,
wherein the capping layer pattern includes a first non-magnetic capping layer, a capping metal layer, and a second non-magnetic capping layer that are sequentially stacked on the oxide layer pattern,
wherein each of the first non-magnetic capping layer and the second non-magnetic capping layer includes a non-magnetic metal,
wherein the capping metal layer includes a metal boride, and
wherein a difference between a boron concentration of the free layer pattern, a boron concentration of the oxide layer pattern, and a boron concentration of the capping metal layer is 10 at % or less.

19. (canceled)

20. The magnetic memory device of claim 18,
wherein the pinned layer pattern comprises a first sub-pinned layer, an anti-ferromagnetic coupling layer, and a second sub-pinned layer that are sequentially stacked on the seed layer pattern,
wherein the first sub-pinned layer and the second sub-pinned layer have magnetization directions opposite to each other, and
wherein the first sub-pinned layer and the second sub-pinned layer are anti-ferromagnetically coupled via the anti-ferromagnetic coupling layer.

21. The magnetic memory device of claim 18,
wherein the free layer pattern comprises a first sub-free layer, an insertion layer, and a second sub-free layer that are sequentially stacked on the tunnel barrier layer pattern,
wherein each of the first sub-free layer and the second sub-free layer comprises boron (B) and at least one of cobalt (Co), iron (Fe) and nickel (Ni), and
wherein the insertion layer has a boron affinity greater than the first sub-free layer and the second sub-free layer.

22. The magnetic memory device of claim 18,
wherein the non-magnetic metal comprises ruthenium (Ru).

23.-28. (canceled)
